(19) United States
(12) Patent Application Publication
(10) Pub. No.: US 2009/0315650 A1
(43) Pub. Date: Dec. 24, 2009

(54) METHOD AND SYSTEM FOR AN INTEGRATED CIRCUIT WITH FERROMAGNETIC LAYERS

(76) Inventor: Ahmadreza Rofougaran, Newport Coast, CA (US)

Correspondence Address: MCANDREWS HELD & MALLOY, LTD, 500 WEST MADISON STREET, SUITE 3400, CHICAGO, IL, 60661, US

(21) Appl. No.: 12/192,249

(22) Filed: Aug. 15, 2008

Related U.S. Application Data
(60) Provisional application No. 61/074,004, filed on Jun. 19, 2008.

(51) Int. Cl. H03H 1/00

(52) U.S. Cl. 333/24 R

(57) ABSTRACT

Methods and systems for an integrated circuit package with ferrimagnetic and/or ferromagnetic layers are disclosed and may include processing a received signal via a single chip comprising one or more integrated layers of ferrimagnetic and/or ferromagnetic material. The received signal may be amplified via the single chip and the one or more integrated layers of ferrimagnetic material and/or ferromagnetic material. Circuits within the single chip may be impedance matched via the one or more integrated layers of ferrimagnetic material and/or ferromagnetic material. The received signal may comprise a microwave signal. The ferromagnetic and/or ferrimagnetic material may be deposited on and/or within the single chip. The ferromagnetic and/or ferrimagnetic material may be deposited on the single chip via an ink printing, spin-on, electron beam deposition, and/or an evaporation technique.

### CROSS-REFERENCE TO RELATED APPLICATIONS/INCORPORATION BY REFERENCE

This application makes reference to and claims priority to U.S. Provisional Application Ser. No. 61/074,004 filed on Jun. 19, 2008, which is hereby incorporated herein by reference in its entirety.

This application also makes reference to:
U.S. patent application Ser. No. 12/036,512 (Attorney Docket No. 19116US01) filed on Feb. 25, 2008;
U.S. patent application Ser. No. 11/956,048 (Attorney Docket No. 19117US01) filed on Dec. 13, 2007;
U.S. patent application Ser. No. 11/956,071 (Attorney Docket No. 19118US01) filed on Dec. 13, 2007;
U.S. patent application Ser. No. 12/057,666 (Attorney Docket No. 19119US01) filed on Mar. 28, 2008;
U.S. patent application Ser. No. 11/956,085 (Attorney Docket No. 19120US01) filed on Dec. 13, 2007;
U.S. patent application Ser. No. 12/040,510 (Attorney Docket No. 19121US01) filed on Feb. 29, 2008;
U.S. patent application Ser. No. 12/036,527 (Attorney Docket No. 19122US01) filed on Feb. 25, 2008;
U.S. patent application Ser. No. 11/954,730 (Attorney Docket No. 19123US01) filed on Dec. 12, 2007;
U.S. patent application Ser. No. 11/956,106 (Attorney Docket No. 19124US01) filed on Dec. 13, 2007;
U.S. patent application Ser. No. 11/956,125 (Attorney Docket No. 19125US01) filed on Dec. 13, 2007;
U.S. patent application Ser. No. 11/954,748 (Attorney Docket No. 19126US01) filed on Dec. 12, 2007;
U.S. patent application Ser. No. 11/954,779 (Attorney Docket No. 19128US01) filed on Dec. 12, 2007;
U.S. patent application Ser. No. 11/954,822 (Attorney Docket No. 19129US01) filed on Dec. 12, 2007;
U.S. patent application Ser. No. 12/057,714 (Attorney Docket No. 19130US01) filed on Mar. 28, 2008; and
U.S. patent application Ser. No. 12/056,505 (Attorney Docket No. 19134US01) filed on Mar. 27, 2008.

Each of the above stated applications is hereby incorporated herein by reference in its entirety.

### FEDERALLY SPONSORED RESEARCH OR DEVELOPMENT

[Not Applicable]

### MICROFICHE/COPYRIGHT REFERENCE

[Not Applicable]

### FIELD OF THE INVENTION

Certain embodiments of the invention relate to wireless communication. More specifically, certain embodiments of the invention relate to a method and system for an integrated circuit with ferromagnetic layers.

### BACKGROUND OF THE INVENTION

Mobile communications have changed the way people communicate and mobile phones have been transformed from a luxury item to an essential part of every day life. The use of mobile phones is today dictated by social situations, rather than hampered by location or technology. While voice connections fulfill the basic need to communicate, and mobile voice connections continue to filter even further into the fabric of every day life, the mobile Internet is the next step in the mobile communication revolution. The mobile Internet is poised to become a common source of everyday information, and easy, versatile mobile access to this data will be taken for granted.

As the number of electronic devices enabled for wireline and/or mobile communications continues to increase, significant efforts exist with regard to making such devices more power efficient. For example, a large percentage of communications devices are mobile wireless devices and thus often operate on battery power. Additionally, transmit and/or receive circuitry within such mobile wireless devices often account for a significant portion of the power consumed within these devices. Moreover, in some conventional communication systems, transmitters and/or receivers are often power inefficient in comparison to other blocks of the portable communication devices. Accordingly, these transmitters and/or receivers have a significant impact on battery life for these mobile wireless devices.

Further limitations and disadvantages of conventional and traditional approaches will become apparent to one of skill in the art, through comparison of such systems with the present invention as set forth in the remainder of the present application with reference to the drawings.

### BRIEF SUMMARY OF THE INVENTION

A system and/or method for an integrated circuit with ferromagnetic layers, substantially as shown in and/or described in connection with at least one of the figures, as set forth more completely in the claims.

Various advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram of an exemplary wireless system, which may be utilized in accordance with an embodiment of the invention.

FIG. 2 is a block diagram illustrating a cross sectional view of an integrated circuit with magnetic layers, in accordance with an embodiment of the invention.

FIG. 3 is a block diagram illustrating a plan view of an integrated circuit with magnetic layers, in accordance with an embodiment of the invention.

FIG. 4 is a block diagram illustrating exemplary steps for implementing an integrated circuit with ferromagnetic layers, in accordance with an embodiment of the invention.

### DETAILED DESCRIPTION OF THE INVENTION

Certain aspects of the invention may be found in a method and system for a single chip with ferromagnetic layers. Exemplary aspects of the invention may comprise processing a received signal via a single chip comprising one or more integrated layers of ferrimagnetic and/or ferromagnetic material. The received signal may be amplified via the single chip and the one or more integrated layers of ferrimagnetic material and/or ferromagnetic material. Circuits within the single chip may be impedance matched via the one or more integrated layers of ferrimagnetic material and/or ferromagnetic material. The received signal may comprise a microwave signal. The ferromagnetic and/or ferrimagnetic material may be deposited on and/or within the single chip. The ferromagnetic and/or ferrimagnetic material may be deposited on the single chip via an ink printing, spin-on, electron beam deposition, and/or an evaporation technique.

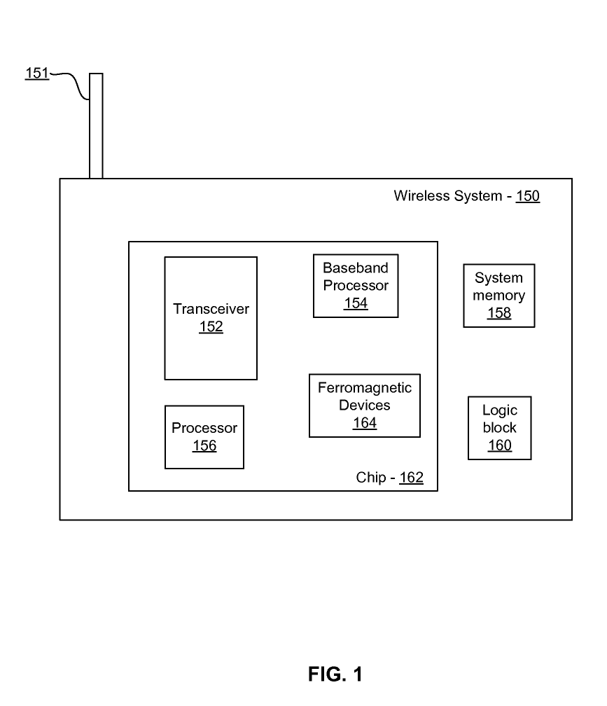

FIG. 1 is a block diagram of an exemplary wireless system, which may be utilized in accordance with an embodiment of the invention. Referring to FIG. 1, the wireless system 150 may comprise an antenna 151, a chip 162, a system memory 158, and a logic block 160. The chip 162 may comprise a transceiver 152, a baseband processor 154, a processor 156, and ferromagnetic devices 164. The antenna 151 may be used for reception and/or transmission of RF signals.

The transceiver 152 may comprise suitable logic, circuitry, and/or code that may be enabled to modulate and upconvert baseband signals to RF signals for transmission by one or more antennas, which may be represented generically by the antenna 151. The transceiver 152 may also be enabled to downconvert and demodulate received RF signals to baseband signals. The RF signals may be received by one or more antennas, which may be represented generically by the antenna 151. Different wireless systems may use different antennas for transmission and reception. The transceiver 152 may be enabled to execute other functions, for example, filtering the baseband and/or RF signals, and/or amplifying the baseband and/or RF signals. Although a single transceiver 152 is shown, the invention is not so limited. Accordingly, the transceiver 152 may be implemented as a separate transmitter and a separate receiver. In addition, there may be a plurality transceivers, transmitters and/or receivers. In this regard, the plurality of transceivers, transmitters and/or receivers may enable the wireless system 150 to handle a plurality of wireless protocols and/or standards including cellular, WLAN and PAN.

The baseband processor 154 may comprise suitable logic, circuitry, and/or code that may be enabled to process baseband signals for transmission via the transceiver 152 and/or the baseband signals received from the transceiver 152. The processor 156 may be any suitable processor or controller such as a CPU or DSP, or any type of integrated circuit processor. The processor 156 may comprise suitable logic, circuitry, and/or code that may be enabled to control the operations of the transceiver 152 and/or the baseband processor 154. For example, the processor 156 may be utilized to update and/or modify programmable parameters and/or values in a plurality of components, devices, and/or processing elements in the transceiver 152 and/or the baseband processor 154. At least a portion of the programmable parameters may be stored in the system memory 158.

Control and/or data information, which may comprise the programmable parameters, may be transferred from other portions of the wireless system 150, not shown in FIG. 1, to the processor 156. Similarly, the processor 156 may be enabled to transfer control and/or data information, which may include the programmable parameters, to other portions of the wireless system 150, not shown in FIG. 1, which may be part of the wireless system 150.

The processor 156 may utilize the received control and/or data information, which may comprise the programmable parameters, to determine an operating mode of the transceiver 152. For example, the processor 156 may be utilized to select a specific frequency for a local oscillator, a specific gain for a variable gain amplifier, configure the local oscillator and/or configure the variable gain amplifier for operation in accordance with various embodiments of the invention. Moreover, the specific frequency selected and/or parameters needed to calculate the specific frequency, and/or the specific gain value and/or the parameters, which may be utilized to calculate the specific gain, may be stored in the system memory 158 via the processor 156, for example. The information stored in system memory 158 may be transferred to the transceiver 152 from the system memory 158 via the processor 156.

The system memory 158 may comprise suitable logic, circuitry, and/or code that may be enabled to store a plurality of control and/or data information, including parameters needed to calculate frequencies and/or gain, and/or the frequency value and/or gain value. The system memory 158 may store at least a portion of the programmable parameters that may be manipulated by the processor 156.

The logic block 160 may comprise suitable logic, circuitry, and/or code that may enable controlling of various functionalities of the wireless system 150. For example, the logic block 160 may comprise one or more state machines that may generate signals to control the transceiver 152 and/or the baseband processor 154. The logic block 160 may also comprise registers that may hold data for controlling, for example, the transceiver 152 and/or the baseband processor 154. The logic block 160 may also generate and/or store status information that may be read by, for example, the processor 156. Amplifier gains and/or filtering characteristics, for example, may be controlled by the logic block 160.

The chip 162 may comprise an integrated circuit with multiple functional blocks integrated within, such as the transceiver 152, the processor 156, the baseband processor 154, and the ferromagnetic devices 164. The number of functional blocks integrated in the chip 162 is not limited to the number shown in FIG. 1. Accordingly, any number of blocks may be integrated on the chip 162 depending on chip space and wireless system 150 requirements, for example.

The ferromagnetic devices 164 may comprise devices formed by depositing and/or embedding ferromagnetic material on and/or within the chip 162. The ferromagnetic devices may be configured by adjusting parameters, such as length, for example, by switching sections in and out of the device via switches in the chip 162.

The magnetic material utilized for the ferromagnetic devices 164 may comprise ferromagnetic and/or ferrimagnetic layers. In this manner, high inductance values may be obtained for devices such as transformers, inductors, and baluns. By utilizing ferromagnetic materials resulting in higher inductances than conventional discrete devices, the size of these devices may be greatly reduced, which may be increasingly important as the frequency of operation of the wireless system 150 may be extended to the 60 GHz range.

The ferrimagnetic material may be anisotropic, such that a magnetic field may align the magnetic dipoles in the material to produce a net (nonzero) dipole moment, which may cause the dipoles to precess at a frequency controlled by the strength of the magnetic field. A signal circularly polarized in the same direction as the precession may interact strongly with the dipole moments, while a signal circularly polarized in the opposite direction of the precession may interact weakly. Thus, signals may propagate through the ferrimagnetic material differently, depending on the direction of travel, which may be exploited to fabricate directional devices such as isolators, circulators, and gyrators. In addition, by controlling the magnetic field, the interaction with signals traveling through the ferrite may be altered, and this may be exploited to fabricate exemplary devices such as phase shifters, switches, and tunable resonators and/or filters.

In operation, control and/or data information, which may comprise the programmable parameters, may be transferred from other portions of the wireless system 150, not shown in FIG. 1, to the processor 156. Similarly, the processor 156 may be enabled to transfer control and/or data information, which may include the programmable parameters, to other portions of the wireless system 150, not shown in FIG. 1, which may be part of the wireless system 150.

The processor 156 may utilize the received control and/or data information, which may comprise the programmable parameters, to determine an operating mode of the transceiver 152. For example, the processor 156 may be utilized to select a specific frequency for a local oscillator, a specific gain for a variable gain amplifier, configure the local oscillator and/or configure the variable gain amplifier for operation in accordance with various embodiments of the invention. In an embodiment of the invention, the processor 156 may configure the ferromagnetic devices for desired impedances required by various blocks within the chip 162. Moreover, the specific frequency selected and/or parameters needed to calculate the specific frequency, and/or the specific gain value and/or the parameters, which may be utilized to calculate the specific gain, may be stored in the system memory 158 via the processor 156, for example. The information stored in system memory 158 may be transferred to the transceiver 152 from the system memory 158 via the processor 156.

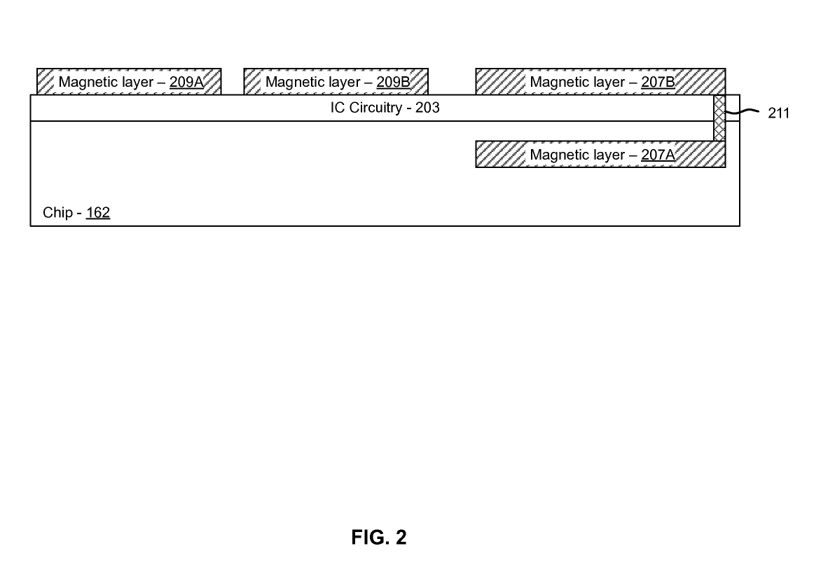

FIG. 2 is a block diagram illustrating a cross sectional view of an integrated circuit with magnetic layers, in accordance with an embodiment of the invention. Referring to FIG. 2, there is shown the chip 162, magnetic layers 207A, 207B, 209A, and 209B, and metal interconnect 211. The number of magnetic layers and metal interconnects may not be limited to the number shown in FIG. 2. Accordingly, there may be any number of interconnects embedded within the chip 162, depending on the device requirements and space limitations of the chip 162.

The chip 162, or integrated circuit, may comprise the transceiver 152 described with respect to FIG. 1, or may also comprise any other integrated circuit within the wireless system 150 that may require inductive components and/or devices.

The magnetic layers 207A, 207B, 209A, and 209B may comprise ferromagnetic and/or ferrimagnetic layers utilized to define devices such as transformers, inductors, baluns, isolators, circulators, and gyrators. The magnetic materials may be deposited on the top, bottom and/or embedded within the chip 162. The magnetic layers 207A, 207B, 209A, and 209B may be spun-on onto the chip 162, or may be deposited by an ink printing technique, for example. In another embodiment of the invention, the magnetic layers 207A, 207B, 209A, and 209B may be deposited utilizing one or more of: electron-beam evaporation, ion-beam deposition, thermal evaporation, chemical vapor deposition and/or plasma deposition, for example. In an embodiment of the invention, the magnetic layers 207A, 207B, 209A, and 209B may be deposited utilizing a redistribution layer (RDL) process for simpler, lower cost applications, or may utilize a multi-layer embedding process allowing for more complex, higher cost structures.

The metal interconnect 211 may comprise one or more metal traces embedded in and/or deposited on the chip 162 that may be utilized to generate electrically conductive paths between components in the chip 162.

In operation, the chip 162 may comprise an RF front end, such as the RF transceiver 152, described with respect to FIG. 1, and may be utilized to transmit and receive RF signals. The chip 162 may comprise inductive devices fabricated on and/or within the chip 162, such as transformers, baluns, and surface mount devices, for example.

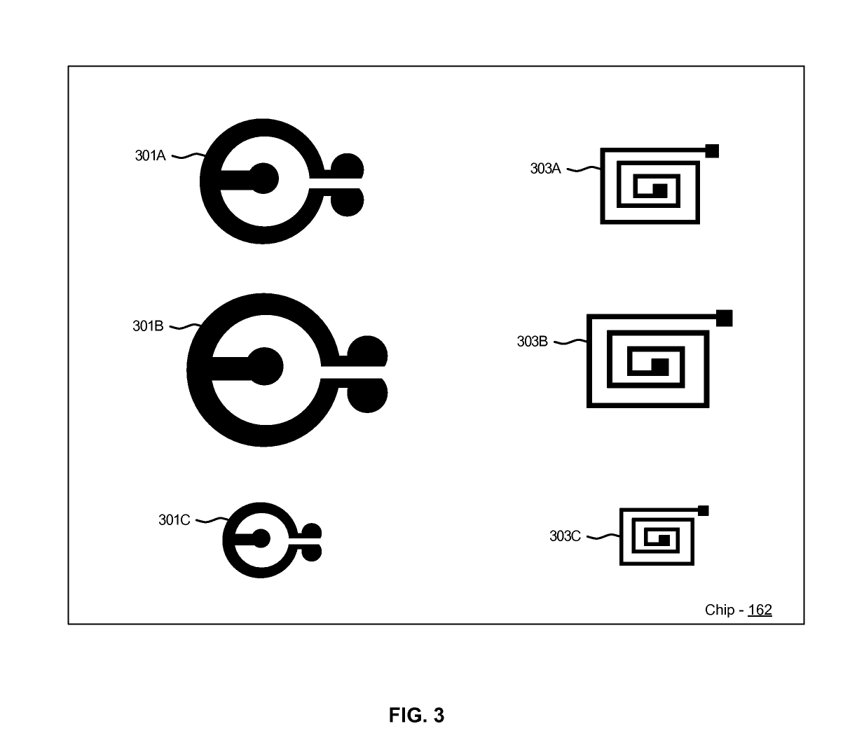

FIG. 3 is a block diagram illustrating a plan view of an integrated circuit with magnetic layers, in accordance with an embodiment of the invention. Referring to FIG. 3, there is shown the chip 162 comprising baluns 301A, 301B, and 301C, and inductors 303A, 303B, and 303C. The number of devices integrated in the chip 162 may not be limited to the number shown in FIG. 3. Accordingly, there may be any number of devices integrated in the chip 162, depending on the device requirements and space limitations of the chip 162.

The baluns 301A, 301B, and 301C may comprise multiple layers of magnetic material deposited on and/or embedded within the chip 162. The baluns 301A, 301B, and 301C may be coupled to circuitry in the chip 162 via metal interconnects, such as the metal interconnect 211 described with respect to FIG. 2. The baluns 301A, 301B, and 301C may be electrically coupled to power amplifiers or low noise amplifiers in the chip 162 and to one or more antennas in the wireless system 150, for example.

The inductors 303A, 303B, and 303C may comprise multiple layers of magnetic material deposited on and/or embedded within the chip 162. The inductors 303A, 303B, and 303C may be coupled to circuitry in the chip 162 via metal interconnects, such as the metal interconnect 211 described with respect to FIG. 2. The inductors 303A, 303B, and 303C may be electrically coupled to circuitry in the chip 162 requiring inductance, such as filters, amplifiers, or impedance matching circuitry, for example.

In operation, the baluns 301A, 301B, and 301C and the inductors 303A, 303B, and 303C may be electrically coupled to circuitry within the chip 162. The baluns 301A, 301B, and 301C may convert a balanced signal from a power amplifier to an unbalanced signal to be transmitted by an antenna, for example. The inductors 303A, 303B, and 303C may provide inductance for filter circuits or impedance matching, for example. The inductors 303A, 303B, and 303C and the baluns 301A, 301B, and 301C may be switched in and out of circuits via CMOS switches in the chip 162, for example. The effective length of one or more of the inductors 303A, 303B, and 303C may be configured via switches coupled along the length of the inductors 303A, 303B, and 303C.

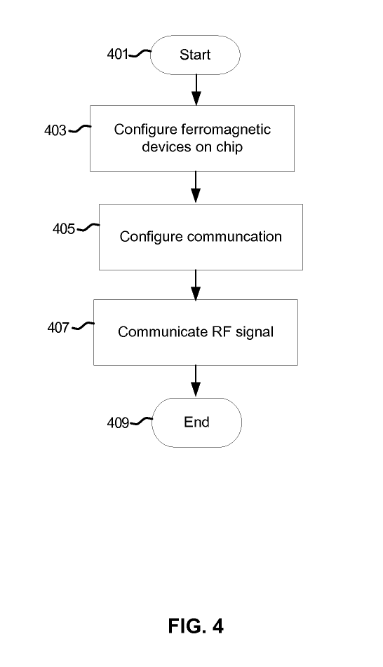

FIG. 4 is a block diagram illustrating exemplary steps for implementing an integrated circuit with ferromagnetic layers, in accordance with an embodiment of the invention. Referring to FIG. 4, in step 403 after start step 401, the ferromagnetic devices on the chip 162 may be configured for appropriate inductance values, for example. In step 405, RF communications may be configured via the ferromagnetic devices and circuitry in the chip 162. In step 407, RF communications may be activated in the wireless system 150, followed by end step 409.

In an embodiment of the invention, a method and system are disclosed for processing a received signal via a single chip 162 comprising one or more integrated layers 207A, 207B, 209A, and 209B of ferrimagnetic and/or ferromagnetic material. The received signal may be amplified via the single chip 162 and the one or more integrated layers 207A, 207B, 209A, and 209B of ferrimagnetic material and/or ferromagnetic material. Circuits within the single chip 162 may be impedance matched via the one or more integrated layers 207A, 207B, 209A, and 209B of ferrimagnetic material and/or ferromagnetic material. The received signal may comprise a microwave signal. The ferromagnetic and/or ferrimagnetic material may be deposited on and/or within the single chip 162. The ferromagnetic and/or ferrimagnetic material may be deposited on the single chip 162 via an ink printing, spin-on, electron beam deposition, and/or an evaporation technique.

Certain embodiments of the invention may comprise a machine-readable storage having stored thereon, a computer program having at least one code section for wireless communication, the at least one code section being executable by a machine for causing the machine to perform one or more of the steps described herein.

Accordingly, aspects of the invention may be realized in hardware, software, firmware or a combination thereof. The invention may be realized in a centralized fashion in at least one computer system or in a distributed fashion where different elements are spread across several interconnected computer systems. Any kind of computer system or other apparatus adapted for carrying out the methods described herein is suited. A typical combination of hardware, software and firmware may be a general-purpose computer system with a computer program that, when being loaded and executed, controls the computer system such that it carries out the methods described herein.

One embodiment of the present invention may be implemented as a board level product, as a single chip, application specific integrated circuit (ASIC), or with varying levels integrated on a single chip with other portions of the system as separate components. The degree of integration of the system will primarily be determined by speed and cost considerations. Because of the sophisticated nature of modern processors, it is possible to utilize a commercially available processor, which may be implemented external to an ASIC implementation of the present system. Alternatively, if the processor is available as an ASIC core or logic block, then the commercially available processor may be implemented as part of an ASIC device with various functions implemented as firmware.

The present invention may also be embedded in a computer program product, which comprises all the features enabling the implementation of the methods described herein, and which when loaded in a computer system is able to carry out these methods. Computer program in the present context may mean, for example, any expression, in any language, code or notation, of a set of instructions intended to cause a system having an information processing capability to perform a particular function either directly or after either or both of the following: a) conversion to another language, code or notation; b) reproduction in a different material form. However, other meanings of computer program within the understanding of those skilled in the art are also contemplated by the present invention.

While the invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiments disclosed, but that the present invention will include all embodiments falling within the scope of the appended claims.

What is claimed is:

1. A method for enabling communication, the method comprising:
processing a received signal via a single chip comprising one or more integrated layers of ferrimagnetic and/or ferromagnetic material.

2. The method according to claim 1, comprising filtering said received signal via said single chip and said one or more integrated layers of ferrimagnetic material and/or ferromagnetic material.

3. The method according to claim 1, comprising amplifying said received signal via said single chip and said one or more integrated layers of ferrimagnetic material and/or ferromagnetic material.

4. The method according to claim 1, comprising matching impedances of circuits within said single chip via said one or more integrated layers of ferrimagnetic material and/or ferromagnetic material.

5. The method according to claim 1, wherein said received signal comprises a microwave signal.

6. The method according to claim 1, wherein said ferromagnetic and/or ferrimagnetic material is deposited on said single chip.

7. The method according to claim 1, wherein said ferromagnetic and/or ferrimagnetic material is embedded within said single chip.

8. The method according to claim 1, wherein said ferromagnetic and/or ferrimagnetic material is deposited on said single chip via an ink printing technique.

9. The method according to claim 1, wherein said ferromagnetic and/or ferrimagnetic material is deposited on said single chip via a spin-on technique.

10. The method according to claim 1, wherein said ferromagnetic and/or ferrimagnetic material is deposited on said single chip via an electron beam deposition and/or an evaporation technique.

11. A system for wireless communication, the system comprising:
a single chip that processes a received signal, wherein said single chip comprises one or more integrated layers of ferrimagnetic material and/or ferromagnetic material.

12. The system according to claim 11, wherein said single chip filters said received signal via said one or more integrated layers of ferrimagnetic material and/or ferromagnetic material.

13. The system according to claim 11, wherein said single chip amplifies said received signal via said one or more integrated layers of ferrimagnetic material and/or ferromagnetic material.

14. The system according to claim 11, wherein said single chip matches impedances of circuits within said integrated circuit via said one or more integrated layers of ferrimagnetic material and/or ferromagnetic material.

15. The system according to claim 11, wherein said received signal comprises a microwave signal.

16. The system according to claim 11, wherein said ferromagnetic and/or ferrimagnetic material is deposited on said single chip.

17. The system according to claim 11, wherein said ferromagnetic and/or ferrimagnetic material is embedded within said single chip.

18. The system according to claim 11, wherein said ferromagnetic and/or ferrimagnetic material is deposited on said single chip via an ink printing technique.

19. The system according to claim 11, wherein said ferromagnetic and/or ferrimagnetic material is deposited on said single chip via a spin-on technique.

20. The system according to claim 11, wherein said ferromagnetic and/or ferrimagnetic material is deposited on said single chip via an electron beam deposition and/or an evaporation technique.
